(19) United States
(12) Patent Application Publication
(10) Pub. No.: US 2025/0029846 A1
(43) Pub. Date: Jan. 23, 2025

(54) APPARATUS AND METHOD FOR SEPARATING WAFER SLICES

(71) Applicant: Yield Engineering Systems, Inc., Fremont, CA (US)

(72) Inventors: Al Stone, Bloomindale, IL (US); Louis Navarro, Canyon Country, CA (US)

(73) Assignee: Yield Engineering Systems, Inc., Fremont, CA (US)

(21) Appl. No.: 18/223,112

(22) Filed: Jul. 18, 2023

(51) Int. Cl. H01L 21/67; H01L 21/02; H01L 21/673; H01L 21/677; H01L 21/68; H01L 21/687

(52) U.S. Cl. CPC H01L 21/67092; H01L 21/0201; H01L 21/67023; H01L 21/67253; H01L 21/67346; H01L 21/67778; H01L 21/68; H01L 21/68742

(57) ABSTRACT

An apparatus to separate a wafer from a pre-sliced boule of wafers may include a conveyor configured to move the pre-sliced boule of wafers from a first end to a second end. A lift yoke, positioned proximate the second end, may include a wafer slot configured to receive a first wafer of the pre-sliced boule therein when the pre-sliced boule is positioned at the second end. A pusher blade may be configured to raise the lift yoke along with the first wafer positioned in its wafer slot from a first position to a second position. The wafer slot may be vertically aligned with the conveyor at the first position and the wafer slot may be positioned above the conveyor in the second position.

### TECHNICAL FIELD

The present disclosure relates to an apparatus and a method for separating wafer slices from a boule.

### BACKGROUND

An ingot of a semiconductor material (such as, for example, Silicon, Gallium Arsenide, Silicon Carbide, etc.) that is grown is commonly known as a boule. After the boule is prepared and annealed, it is sliced or diced into individual wafers of the desired thickness (e.g., 180 microns). Individual wafers are then separated from the sliced boule and transferred to slots in process cassettes and subject to additional processing steps (e.g., to fabricate integrated circuit devices thereon). In some applications, separating individual wafers from a sliced boule is done manually. Automating the separation of individual wafers from a sliced boule may increase accuracy and efficiency and reduce time and costs.

### SUMMARY

Embodiments of an apparatus and related methods for separating individual wafers from a pre-sliced boule are disclosed.

In one embodiment, an apparatus to separate a wafer from a pre-sliced boule of wafers is disclosed. The apparatus may include a conveyor configured to move the pre-sliced boule of wafers from a first end to a second end. One end of the pre-sliced boule may include a first wafer and a second wafer adjacent to the first wafer. A lift yoke may be positioned proximate the second end. The lift yoke may include a wafer slot configured to receive the first wafer therein when the pre-sliced boule of wafers is positioned at the second end. A pusher blade may be configured to raise the lift yoke along with the first wafer positioned in the wafer slot from a first position to a second position. The wafer slot may be vertically aligned with the conveyor at the first position and the wafer slot may be positioned above the conveyor in the second position.

Various embodiments of the disclosed apparatus may additionally or alternatively include one of more of the following features: the pusher blade may be further configured to lower the lift yoke from the second position to the first position, wherein the second wafer is configured to received in the wafer slot when the lift yoke is back at the first position; the apparatus may further include a fixed stop positioned proximate the second end of the conveyor, wherein the fixed stop is configured to stop the pre-sliced boule of wafers at the second end; the fixed stop may include a plurality of elastomeric pads configured to contact a surface of a wafer of the pre-sliced boule of wafers when the pre-sliced boule of wafers is positioned at the second end; the lift yoke may be positioned between the second end of the conveyor and the fixed stop; a size of the wafer slot and the size of the first wafer may be substantially the same; the conveyor may include a pair of angular belts configured to cradle the pre-sliced boule of wafers therebetween; wherein the conveyor may be positioned in a liquid bath; the apparatus may further include a pusher slug positioned proximate the first end of the conveyor, wherein the pusher slug is configured to push the pre-sliced boule of wafers from the first end towards the second end; when the lift yoke lift is positioned at the second position, the first wafer positioned in the wafer slot may be accessible by a robotic wafer-removal arm; and the apparatus may further include a sensor configured to detect an end of wafers in the pre-sliced boule of wafers.

In another embodiment, an apparatus to separate a wafer from a pre-sliced boule of wafers is disclosed. The apparatus may include a conveyor configured to move the pre-sliced boule of wafers from a first end to a second end. One end of the pre-sliced boule may include a first wafer and a second wafer adjacent to the first wafer. A fixed stop may be positioned proximate the second end of the conveyor and configured to stop the pre-sliced boule of wafers at the second end. A lift yoke may be positioned between the second end of the conveyor and the fixed stop. The lift yoke may include a circular wafer slot configured to receive the first wafer therein when the pre-sliced boule of wafers is stopped by the fixed stop. A pusher blade may be configured to raise the lift yoke along with the first wafer positioned in the wafer slot from a first position to a second position, wherein the wafer slot is vertically aligned with the conveyor in the first position and the wafer slot is positioned above the conveyor in the second position. The pusher blade may also be configured to lower the lift yoke from the second position to the first position, wherein the second wafer is configured to received in the wafer slot when the lift yoke is back at the first position.

Various embodiments of the current disclosure may additionally or alternatively include the following features: a diameter of the wafer slot and the diameter of the first wafer may be substantially the same; the conveyor may include a pair of angular belts configured to cradle the pre-sliced boule of wafers therebetween; the conveyor may be positioned in a liquid bath; and the apparatus may further include a pusher slug positioned proximate the first end of the conveyor and configured to push the pre-sliced boule of wafers from the first end towards the second end.

In yet another embodiment, a method of removing of removing a wafer from a pre-sliced boule of wafers is disclosed. The method may include moving the pre-sliced boule of

[symbol]

For simplicity and clarity of illustration, the figures depict the general structure of the various described embodiments. Details of well-known components or features may be omitted to avoid obscuring other features, since these omitted features are well-known to those of ordinary skill in the art. Further, features in the figures are not necessarily drawn to scale. The dimensions of some features may be exaggerated relative to other features to improve understanding of the exemplary embodiments. One skilled in the art would appreciate that the features in the figures are not necessarily drawn to scale and, unless indicated otherwise, should not be viewed as representing dimensions or proportional relationships between different features in a figure. Additionally, even if it is not expressly mentioned, aspects described with reference to one embodiment or figure may also be applicable to, and may be used with, other embodiments or figures.

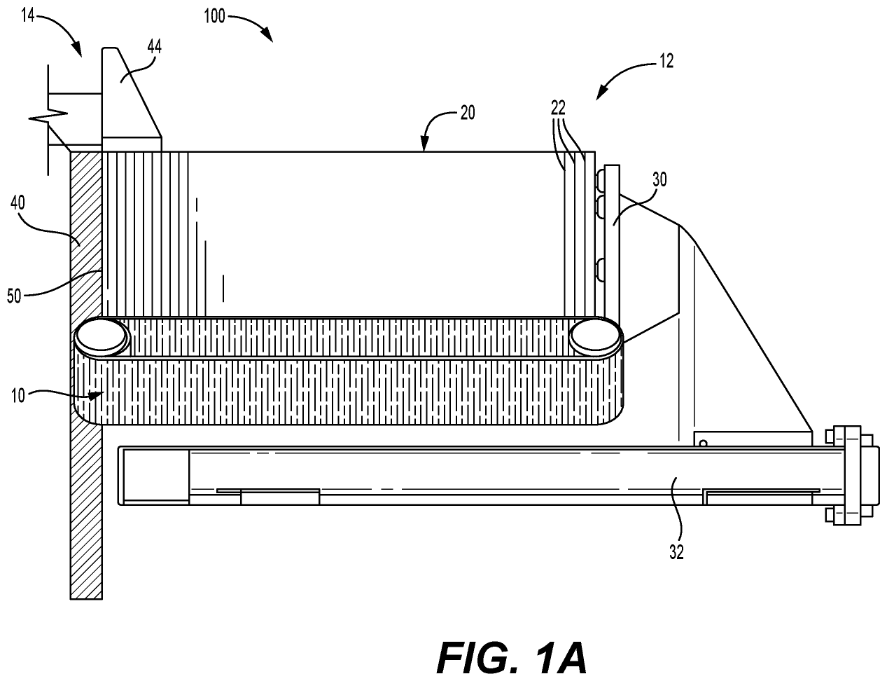

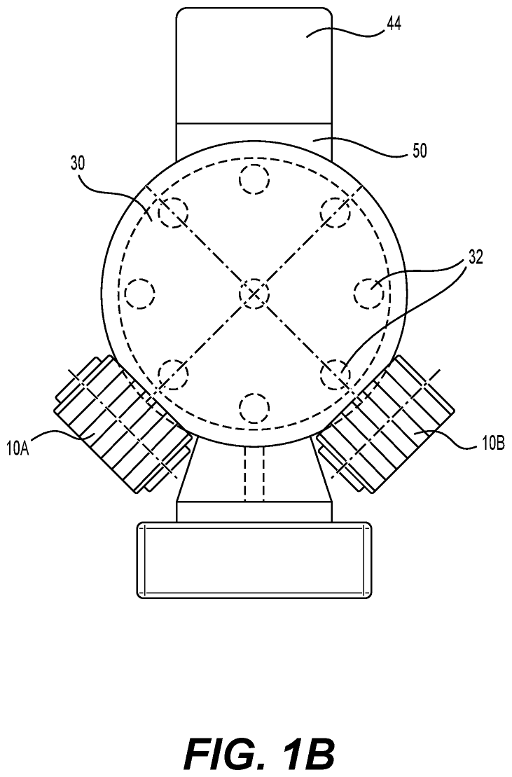

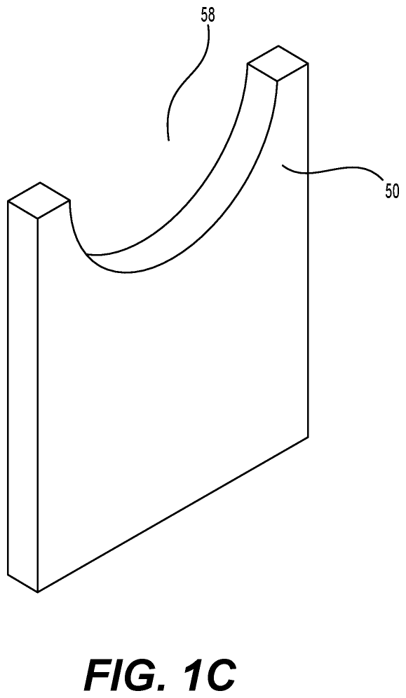

FIGS. 1A and 1B illustrate different views of an exemplary apparatus of the current disclosure;

FIG. 1C illustrates an exemplary component of the apparatus of FIG. 1A;

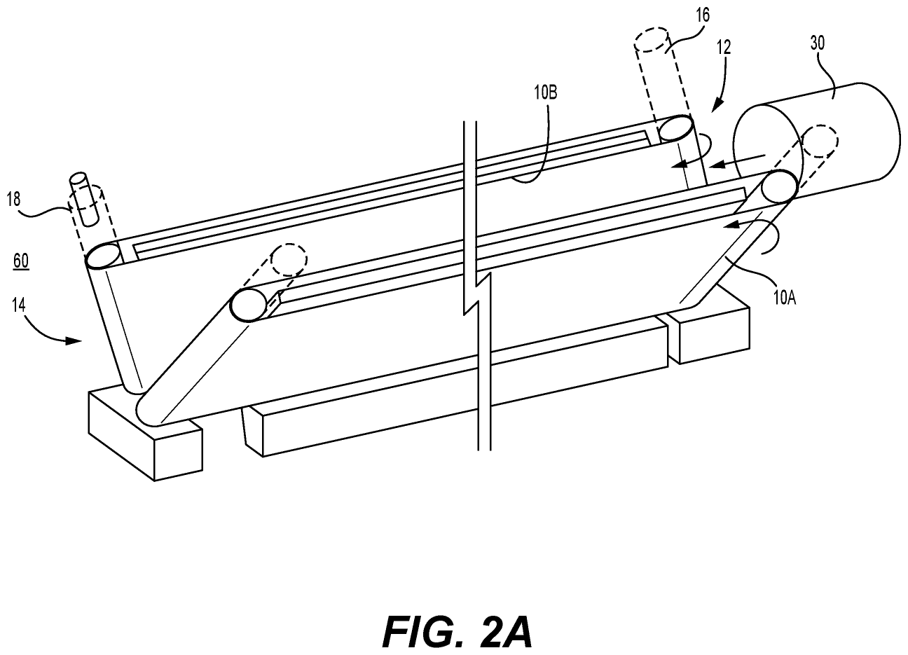

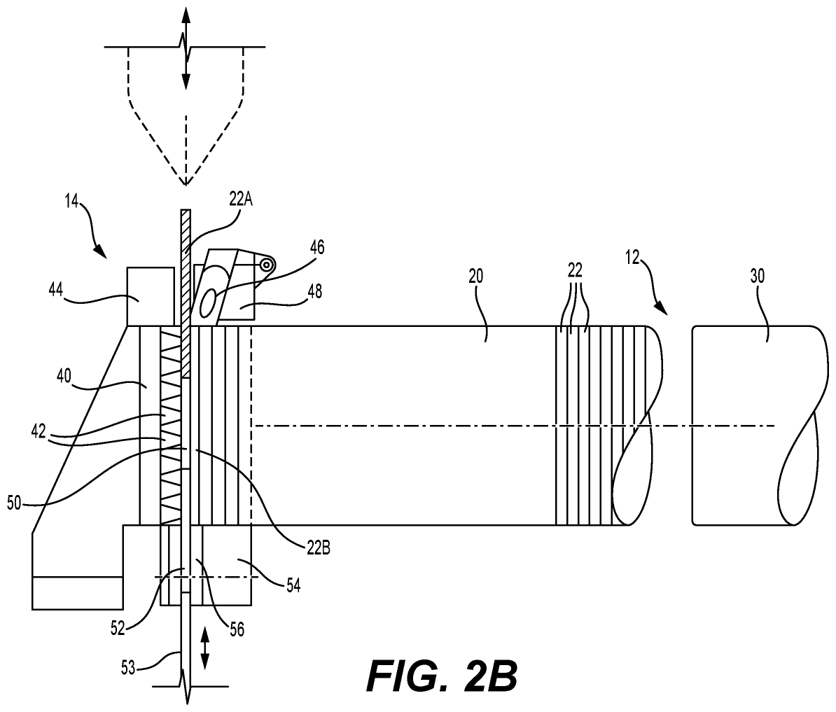

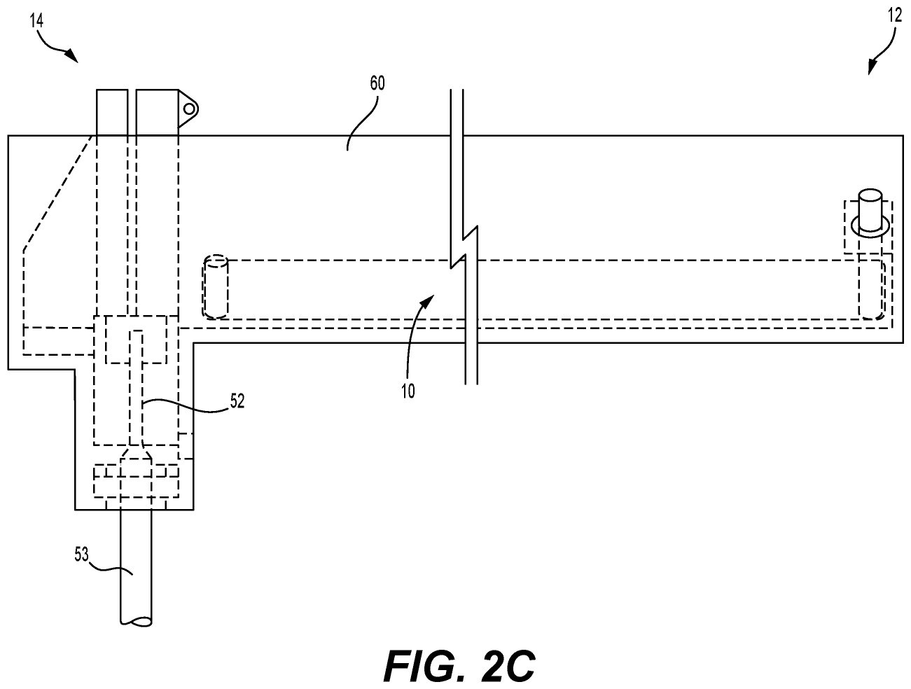

FIGS. 2A-2C are schematic illustrations of different views of the exemplary apparatus of FIG. 1A; and

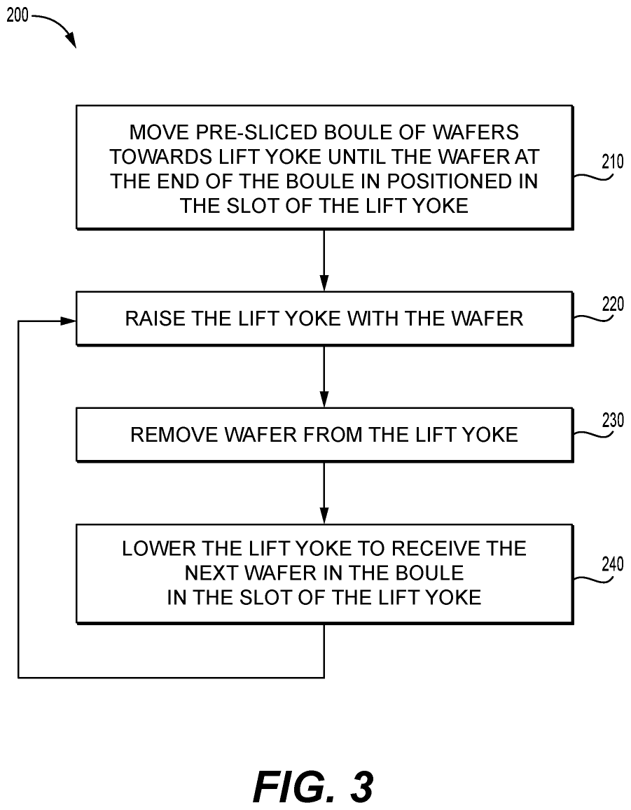

FIG. 3 is a flow chart illustrating an exemplary method of using the apparatus of FIG. 1A.

### DETAILED DESCRIPTION

All relative terms such as “about,” “substantially,” “approximately,” etc., indicate a possible variation of ±10% (unless noted otherwise or another degree of variation is specified). For example, a feature disclosed as being about “t” units wide (or length, thickness, depth, etc.) may vary in width from (t−0.1t) to (t+0.1t) units. In some cases, the specification also provides context to some of the relative terms used. For example, a structure (e.g., a coating edge) described as being substantially linear may deviate by ±10% from being linear. Further, a range described as varying from, or between, 5 to 10 (5-10), includes the endpoints (i.e., 5 and 10).

Unless otherwise defined, all terms of art, notations, and other scientific terms or terminology used herein have the same meaning as commonly understood by persons of ordinary skill in the art to which this disclosure belongs. Some components, structures, and/or processes described or referenced herein are well understood and commonly employed using conventional methodology by those skilled in the art. These components, structures, and processes will not be described in detail. All patents, applications, published applications and other publications referred to herein as being incorporated by reference are incorporated by reference in their entirety. If a definition or description set forth in this disclosure is contrary to, or otherwise inconsistent with, a definition and/or description in these references, the definition and/or description set forth in this disclosure controls over those in references incorporated by reference. None of the references described or referenced herein is admitted as prior art relative to the current disclosure.

The discussion below describes an exemplary apparatus and method used to separate (or singulate) a wafer from a sliced boule. It should be noted that the specific features of the described apparatus, such as, for example, the type of wafer separated are not limitations. Instead, embodiments of the described apparatus may be used to separate any type of wafer in any suitable application. In the discussion below, the term “wafer” is used broadly to refer to any type of substrate (semiconductor, glass, metal, plastic, etc.) of any shape (round, square, rectangular, etc.) that is formed as a boule or ingot and then separated (e.g., sliced, diced, laser cut, etc.) to form individual substrates.

FIGS. 1A and 1B illustrate different views of an exemplary apparatus 100 that may be used to separate individual wafers from a pre-sliced boule of wafers. FIG. 1A illustrates a side view and FIG. 1B illustrates an end view. FIG. 1C illustrates a perspective view of one component of apparatus 100. FIGS. 2A-2C are schematic illustrations of different portions of apparatus 100. FIG. 2A is a perspective view and FIGS. 2B and 2C are side views. In the discussion below reference will be made to FIGS. 1A-1C and 2A-2C. Apparatus 100 includes a boule conveyor 10 positioned in a process tank 60 or bath (see FIG. 2C) containing a liquid (e.g., a heated surfactant solution or any other suitable liquid). A pre-sliced boule 20 (see FIG. 2B) of wafers 22 sits on the conveyor 10 in tank 60. Typically, the boule is attached to a support member (e.g., a bar, rod, etc.) using an adhesive material while it is sliced into individual wafers 22 to hold the sliced wafers in place. The liquid in tank 60 is utilized to release the boule 20 of sliced wafers 22 from the support member. The support member may be removed before a separation cycle is initiated to separate individual wafers 22 from the pre-sliced boule 20.

Conveyor 10 may include a pair of angled friction drive belts 10A, 10B (see FIG. 2A) configured to support or cradle boule 20 therebetween. Belts 10A and 10B may extend from an inlet end 12 to an exit end 14 of conveyor 10, and may arranged in a V-configuration such that boule 20 may be supported between the angled surfaces of the belts (see FIG. 2A). Conveyor 10 may include a drive shaft 16 (e.g., that protrudes out of tank 60) and a drive mechanism configured to move belts 10A, 10B over pulleys such that boule 20 moves from inlet end 12 to exit end 14 of conveyor 10. In some embodiments, conveyor 10 may be triggered to move when the separation cycle of a boule 20 is initiated. Separation cycle refers to the process of separating (and removing) individual wafers 22 from boule 20. Initiation of the separation cycle may be triggered by any method. For example, the separation cycle may be initiated when boule 20 is placed on conveyor 10, when boule 20 reaches a particular location on conveyor 10, when the support member that holds wafers 22 together is removed from boule 20, when an operator presses a button, etc. The separation cycle may also be terminated by any method. For example, when an operator presses a button, when boule 20 reaches a particular location on conveyor 10, etc. In some embodiments, a sensor 18 may be positioned at the (or proximate the) exit end 14 of conveyor 10 to detect the end of wafers 22 in the boule. In other words, sensor 18 may detect that there are no more wafers 22 in the boule 20 to be separated. In some embodiments, the signals from sensor 18 may be trigger the end of the separation cycle of boule 20. Any type of sensor (e.g., proximity sensor, etc.) may be used as sensor 18.

A pusher slug 30 of apparatus 100 may be configured to push the pre-sliced boule 20 from inlet end 12 towards outlet end 14 of conveyor 10 (see, e.g., FIG. 2A). Pusher slug 30 may have any configuration that enables it to contact the back side of boule 20 sitting in the liquid on conveyor 10 and push it towards exit end 14 (see FIG. 2B). In some embodiments, pusher slug 30 may include a piston-like cylindrical component or a disk-like plate with elastomeric contact points on the surface facing the back side of boule 20 sitting on conveyor 10. The elastomeric contact points may be arranged to contact the back side of boule 20 and provide some compliance when boule 20 is being pushed. Pusher slug 30 may be coupled to an actuator or a linear slide assembly 32 positioned outside tank 60 and configured to move slug 30 from inlet end 12 towards exit end 14 of conveyor 10. In some embodiments, the previously described end-of-wafer sensor 18 may be positioned on, or coupled to, slug 30.

Referring primarily to FIGS. 2B and 2C, a fixed stop 40 may be positioned proximate the exit end 14 of conveyor 10 to stop the boule 20 (moving on conveyor 10) at the exit end 14. Fixed stop 40 may include a plurality of elastomeric pads 42 on its surface facing boule 20. Pads 42 may be button-like projections that are configured to contact the surface of the first wafer 22 (marked 22A in FIG. 2B) on boule 20 without causing any damage (e.g., chips, cracks, etc.) to the wafer. In some embodiments, a hard elastomeric material (e.g., having a hardness of 90 durometers or more) may be used for pads 42. Any number of pads 42 may be provided. In some embodiments, pads 42 may be symmetrically arranged on stop 40 such that the wafer 22 (on boule 20) that it contacts does not tilt when boule 20 is stopped at exit end 14.

A lift yoke 50 (best seen in FIG. 1C) may also be positioned proximate the exit end 14 of conveyor 10. In some embodiments, lift yoke 50 may be positioned between the exit end 14 of conveyor 10 and the fixed stop 40. Lift yoke 50 may be component with an opening (e.g., a through-hole opening) or a wafer slot 58 that is shaped to receive a wafer 22 therein. As illustrated in FIG. 1C, slot 58 may be an arc-shaped opening through which the pads 42 of fixed stop 20 extends towards the boule 20. In some embodiments, the slot 58 may be shaped like a chord of a circle having a radius substantially similar to that of wafer 22. In some embodiments, slot 58 may be a semicircular (e.g., half of a circle) opening. Lift yoke 50 may be positioned such that the first wafer 22A on boule 20 is received in its slot 58 when boule 20 is stopped by pads 42 of fixed stop 40. When received in slot 58, the bottom portion of the first wafer 22A may be supported by the arc-shaped bottom wall of the slop 58. To securely receive a wafer in wafer slot 58, the shape (and size) of slot 58 may be substantially similar to that of wafer 22. For example, when wafer 22 is a circular substrate having a diameter of (for example) 20 mm and a thickness of (for example) 2 mm, wafer slot 58 may be a arc-shaped opening with a radius equal to or slightly greater than 10 mm (to receive wafer while accounting for manufacturing tolerances) and a thickness slightly less than 2 mm (to receive wafer 22A without a portion of the next wafer 22B also entering the slot). When wafer slot 58 of lift yoke 50 is vertically aligned with conveyor 10 (to receive the last wafer on boule 20 in slot 58), a portion of lift yoke 50 below slot 58 may extend below conveyor 10 through a pusher blade guide 56 in a pusher blade holder 54 to contact a pusher blade 52 (see FIG. 2B).

The bottom end of the lift yoke 50 may contact the top end of pusher blade 52. Pusher blade 52 may be coupled to an air slide 53 and configured to move vertically up and down through the pusher blade guide 56. Pusher blade 52 and air slide 53 may be configured to push and move lift yoke 50 away from conveyor 10 (e.g., raise) and lower the lift yoke 50 back towards conveyor 10. For example, in the up-stroke (of air slide 53), pusher blade 52 may move lift yoke 50 and its wafer slot 58 up away from conveyor 10, and on the down-stroke (of air slide 53) pusher blade 52 may move the lift yoke 50 and its wafer slot 58 back down such that slot 58 is again vertically aligned with the conveyor. For convenience, the configuration of lift yoke 50 with its wafer slot 58 vertically aligned with conveyor 10 such that a wafer 22 of boule 20 may be received in (e.g., slide in) wafer slot 58 may be referred to as the “home position” of lift yoke 50. With reference to FIG. 2B, when the air slide 53 moves the pusher blade 52 up, the pusher blade 52 in turn pushes lift yoke 50 (with the first wafer 52A in its wafer slot 58) up through an exit guide 44 thereby separating the wafer 22A from boule 20. A spring-loaded stripper blade 46, coupled to a blade housing block 48, may press against (or be biased against) exit guide 44 to prevent the next-to-last wafer (or second wafer 22B) of boule 20 (see FIG. 2B) from being lifted up with the first wafer 22A. In the raised position of the lift yoke 50, wafer slot 58 and the exposed top portion of first wafer 22A may be accessible, for example, by a wafer-removing arm of robotic gripper 70.

When lift yoke 50 is its raised position, robotic gripper 70 may grasp the exposed top end (of first wafer 22A) and remove the first wafer 22A from wafer slot 58 and, for example, load it into a slot of a process cassette for further processing. After the first wafer 22A is removed from wafer slot 58, pusher blade 52 may lower lift yoke 50 back down to its home position such that wafer slot 58 is once again vertically aligned with conveyor 20 to receive the next wafer on boule 20 (e.g., wafer 22B which is now the first wafer in boule 20) in wafer slot 58. That is, when lift yoke 50 is lowered back to its home position, its wafer slot 58 gets vertically aligned with the boule on conveyor 10 such that the last wafer on the boule slides into the now open wafer slot 58. Wafer 22B may now be separated from boule 20 and removed by the lift yoke 50 in the same manner described above. This separation cycle may continue until all the wafers 22 from boule 20 are removed. When a signal from sensor 18 indicates that there are no more wafers in boule 20 be removed (or based on any other trigger), the separation cycle of boule 20 may be terminated until another pre-sliced boule of wafers is loaded on conveyor 10 to begin another separation cycle.

Thus, in apparatus 100, conveyor 10 drives the pre-sliced boule 20 forward until it is stopped by the fixed stop 40 and the first sliced wafer 22A at the end of the boule enters slot 58 of lift yoke 50. The air slide powered pusher blade 52 is then actuated upward, and as it moves upward, it pushes the lift yoke with a single separated wafer (in wafer slot 58) from the boule upwards. The wafer passes by a spring-loaded stripper blade 46 and exit guide 44 until the wafer is high enough to be removed from wafer slot 58 (e.g., by a robotic gripper arm). The lift yoke 50 (e.g., the wall-like portion of lift yoke 50 below slot 58) and/or the pusher blade 52 may be configured to hold back the oncoming wafers 22 in boule 20 until the yoke 50 is returned to its home position when the boule advances and the next wafer in boule (i.e., the wafer at the end of the boule) again advances into (or slides into) the wafer slot and the separation cycle repeats. It should be noted that the configuration of the apparatus, and the shape and structure of its components (e.g., lift yoke 50, wafer slot 58, stop 40, slug 30, conveyor 10, and other features), illustrated in the figures are merely exemplary. A person skilled in the art would recognize that the illustrated features may have many other configurations.

FIG. 3 is a flow chart that illustrates an exemplary method 200 for separating a wafer from a sliced boule of wafers. A pre-sliced boule of wafers may be moved towards a lift yoke until the first wafer in the boule (i.e., the wafer at the end of the boule) is positioned in a wafer slot of the lift yoke. (Step 210). The lift yoke may now be raised along with the wafer. (Step 220). The wafer in the wafer slot of the lift yoke may now be removed. (Step 230). The wafer may be removed in any manner. In some embodiments, a robotic wafer-removal arm may grasp and pick the wafer from the wafer slot and transfer it elsewhere (e.g., to an open slot in a process cassette for further processing). The lift yoke may be lowered to its home position to receive the next wafer in the boule in the lift yoke slot. (Step 240). The lift yoke may again be raised to remove the wafer and the process continued until all the wafers in the boule are separated and removed.

Although in the description above, some features were disclosed with reference to specific embodiments, a person skilled in the art would recognize that this is only exemplary, and the features are applicable to all disclosed embodiments. Other embodiments of the apparatus, its features and components, and related methods will be apparent to those skilled in the art from consideration of the disclosure herein.

What is claimed is:

1. An apparatus to separate a wafer from a pre-sliced boule of wafers, comprising:
a conveyor configured to move the pre-sliced boule of wafers from a first end to a second end, wherein one end of the pre-sliced boule includes a first wafer and a second wafer adjacent to the first wafer;
a lift yoke positioned proximate the second end, wherein the lift yoke includes a wafer slot and configured to receive the first wafer therein when the pre-sliced boule of wafers is positioned at the second end; and
a pusher blade configured to raise the lift yoke along with the first wafer positioned in the wafer slot from a first position to a second position, wherein the wafer slot is vertically aligned with the conveyor at the first position and the wafer slot is positioned above the conveyor in the second position.

2. The apparatus of claim 1, wherein the pusher blade is further configured to lower the lift yoke from the second position to the first position, wherein the second wafer is configured to received in the wafer slot when the lift yoke is back at the first position.

3. The apparatus of claim 1, further including a fixed stop positioned proximate the second end of the conveyor, wherein the fixed stop is configured to stop the pre-sliced boule of wafers at the second end.

4. The apparatus of claim 3, wherein the fixed stop includes a plurality of elastomeric pads configured to contact a surface of a wafer of the pre-sliced boule of wafers when the pre-sliced boule of wafers is positioned at the second end.

5. The apparatus of claim 3, wherein the lift yoke is positioned between the second end of the conveyor and the fixed stop.

6. The apparatus of claim 1, wherein the wafer slot is an opening having a semicircular shape.

7. The apparatus of claim 1, wherein the conveyor includes a pair of angular belts configured to cradle the pre-sliced boule of wafers therebetween.

8. The apparatus of claim 1, wherein the conveyor is positioned in a liquid bath.

9. The apparatus of claim 1, further including a pusher slug positioned proximate the first end of the conveyor, wherein the pusher slug is configured to push the pre-sliced boule of wafers from the first end towards the second end.

10. The apparatus of claim 1, wherein when the lift yoke lift is positioned at the second position, the first wafer positioned in the wafer slot is accessible by a robotic wafer-removal arm.

11. The apparatus of claim 1, further including a sensor configured to detect an end of wafers in the pre-sliced boule of wafers.

12. An apparatus to separate a wafer from a pre-sliced boule of wafers, comprising:
a conveyor configured to move the pre-sliced boule of wafers from a first end to a second end, wherein one end of the pre-sliced boule includes a first wafer and a second wafer adjacent to the first wafer;
a fixed stop positioned proximate the second end of the conveyor and configured to stop the pre-sliced boule of wafers at the second end;
a lift yoke positioned between the second end of the conveyor and the fixed stop, wherein the lift yoke includes an arc-shaped wafer slot configured to receive the first wafer therein when the pre-sliced boule of wafers is stopped by the fixed stop; and
a pusher blade configured to (a) raise the lift yoke along with the first wafer positioned in the wafer slot from a first position to a second position, wherein the wafer slot is vertically aligned with the conveyor in the first position and the wafer slot is positioned above the conveyor in the second position, and (b) lower the lift yoke from the second position to the first position, wherein the second wafer is configured to received in the wafer slot when the lift yoke is back at the first position.

13. The apparatus of claim 12, wherein the wafer slot is a semicircular opening having a diameter substantially the same as the diameter of the first wafer.

14. The apparatus of claim 12, wherein the conveyor includes a pair of angular belts configured to cradle the pre-sliced boule of wafers therebetween.

15. The apparatus of claim 14, wherein the conveyor is positioned in a liquid bath.

16. The apparatus of claim 12, further including a pusher slug positioned proximate the first end of the conveyor, wherein the pusher slug is configured to push the pre-sliced boule of wafers from the first end towards the second end.

17. A method of removing of removing a wafer from a pre-sliced boule of wafers, comprising:
moving the pre-sliced boule of wafers from a first end to a second end on a conveyor, wherein one end of the pre-sliced boule includes a first wafer and a second wafer adjacent to the first wafer;
receiving the first wafer in a wafer slot of a lift yoke when the pre-sliced boule of wafers is positioned at the second end; and
raising the lift yoke along with the first wafer positioned in the wafer slot from a first position to a second position, wherein the wafer slot is vertically aligned with the conveyor in the first position and the wafer slot is positioned above the conveyor in the second position.

18. The method of claim 17, further including removing the first wafer from the wafer slot when the lift yoke is positioned at the second position.

19. The method of claim 18, further including lowering the lift yoke from the second position to the first position after the removing, wherein the second wafer is configured to be received in the wafer slot when the lift yoke is lowered to the first position.

20. The method of claim 17, wherein moving the pre-sliced boule of wafers from a first end to a second end includes moving the pre-sliced boule of wafers through a liquid bath on the conveyor.
